(19) United States
(12) Patent Application Publication
(10) Pub. No.: US 2008/0191323 A1
(43) Pub. Date: Aug. 14, 2008

(54) Semiconductor package and its manufacturing method

(76) Inventor: En-Min Jow, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/602,228

(22) Filed: Nov. 21, 2006

(30) Foreign Application Priority Data
Oct. 5, 2006 (TW) 95137121

(51) Int. Cl. H01L 23/495; H01L 21/56

(52) U.S. Cl. 257/666; 438/15; 257/E21.502; 257/E23.031

(57) ABSTRACT

A semiconductor package and its manufacturing method disclosed herein include a lead frame, a chip, an encapsulant, and a passive component arranged on at least any one of the outer lead portions and a supporting finger of the lead frame, wherein the passive component are exposed to the encapsulant. After the molding process, the electrical testing of the chip package can be performed before attaching the passive component on the lead frame, so as to get the higher reliability and reduce the damage probability of the passive component.

### BACKGROUND OF THE INVENTION

1. Field of the Invention

The present invention relates to a semiconductor packaging technology, and more particularly, to a semiconductor package and its manufacturing method.

2. Description of the Prior Art

Along with the progress of the semiconductor technology and the increasing density of the integrated circuits, the leads of the packaging elements become more and more and the requirements of the speed get higher so that it is a tendency to produce the small-sized, high-speed, and high-density packaging elements.

Along with the high speed of the electrical package, the noise from the direct current and the ground circuit can be an important issue. Therefore, generally speaking, the passive component, such as a capacitor, can be utilized to reduce the noise that the power source generated. Such as shown in FIG. 1, FIG. 1 is a cross-sectional schematic diagram to illustrate the conventional package structure with a passive component. This structure includes a lead frame 100, a chip 300, a passive component 200 and a molding compound 400. Wherein the lead frame 100 has a die pad 102; the chip 300 and the passive component 200 are fixed and set on the die pad 102; the molding compound 400 covers the chip 300, the passive component 200, and some portion of the lead frame 100; after that, the whole package is tested to be a good product or a failed one by an electrical testing.

However, in the aforementioned structure, the packaging process of the chip 300 and the passive component 200 is before the electrical testing so that the production yield depends on the testing result. If the testing result is failed, every element (including the chip 300 and the passive component 200) and the molding material (for example the molding compound 400) may be discarded and result in a waste of production cost and process time. On the other hand, due to the sealed structure, it is hard to investigate the reason inside the package when the failure of the package is examined; so as to affect the production yield. Consequently, how to overcome the questions hereinabove is a necessary and urgent issue for most manufacturers.

### SUMMARY OF THE INVENTION

In order to solve the aforementioned problems, one object of the present invention is to provide a semiconductor package and its manufacturing method which the passive component is exposed to the molding compound. After the packaging process, the electrical testing is performed, then deciding whether to arrange the passive component on the package or not so as to reduce the damage probability.

One object of the present invention is to provide a semiconductor package and its manufacturing method which the package and the passive component can be verified respectively so as to improve the process reliability and reduce the production cost.

One object of the present invention is to provide a semiconductor package and its manufacturing method which the passive component can be externally disposed on the molding compound so as to directly examine the connection of the passive component and prevent the passive component from damaging during the molding process.

To achieve the objects mentioned above, one embodiment of the present invention is to provide a semiconductor structure, which includes: a lead frame with a supporting element and a plurality of leads, wherein any one of those leads has an inner lead portion and an outer lead portion; a chip set on the supporting element, and electrically connected to those inner lead portions via a conductive connecting element; an encapsulant covering the chip, the conductive connecting element and those inner lead portions; and a passive component electrically connected with any two of those outer lead portions.

To achieve the objects mentioned above, another embodiment of the present invention is to provide a semiconductor structure, which includes: a lead frame with a supporting element and a plurality of leads, wherein the supporting element have a plurality of supporting fingers and any one of those leads has an inner lead portion and an outer lead portion; a chip set on one the of the supporting element, and electrically connected to those inner lead portions via a conductive connecting element; an encapsulant covering the chip, the conductive connecting element, the inner lead portion and partial of those supporting fingers; and a passive component electrically connected with at least any one of those exposed supporting fingers and any one of those outer lead portions.

To achieve the objects mentioned above, another embodiment of the present invention is to provide a manufacturing method for a semiconductor structure, which includes: providing a lead frame with a supporting element and a plurality of leads, wherein any one of those leads has an inner lead portion and an outer lead portion; disposing a chip on the supporting element, and electrically connecting the chip to those inner lead portions via a conductive connecting element; forming an encapsulant to cover the chip, the conductive connecting element and those inner lead portions; and disposing a passive component on at least any one of those outer lead portions and the supporting element.

Other objects, technical contents, features and advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is the cross-sectional schematic diagram to illustrate the conventional package structure;

FIG. 2 is the cross-sectional schematic diagram to illustrate the semiconductor package structure according to one embodiment of the present invention;

FIG. 3A is the top-view schematic diagram to illustrate the semiconductor package structure according to the first embodiment of the present invention;

FIG. 3B is the top-view schematic diagram to illustrate the semiconductor package structure according to one embodiment of the present invention;

FIG. 4A is the top-view schematic diagram to illustrate the semiconductor package structure according to the second embodiment of the present invention;

FIG. 4B is the top-view schematic diagram to illustrate the semiconductor package structure according to one embodiment of the present invention; and

FIG. 5A, FIG. 5B and FIG. 5C are the cross-sectional schematic diagrams to illustrate the semiconductor package manufacturing method according to one embodiment of the present invention.

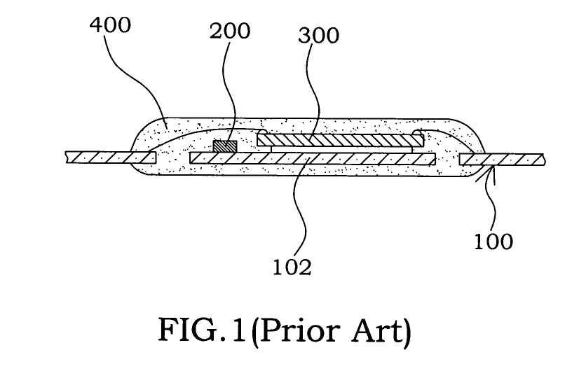

### DESCRIPTION OF THE PREFERRED EMBODIMENT

The detailed explanation of the present invention is described as following. The described preferred embodiments are presented for purposes of illustrations and description, and they are not intended to limit the scope of the present invention.

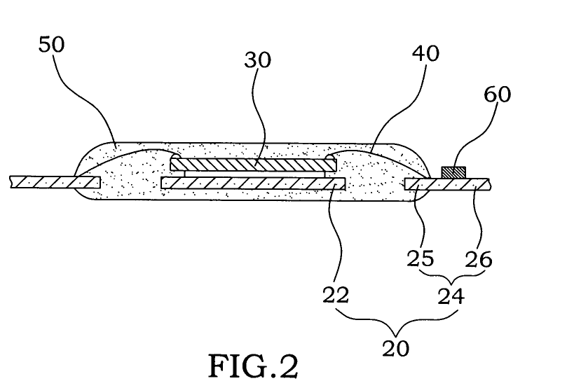

FIG. 2 is the cross-sectional schematic diagram to illustrate the semiconductor package structure according to the first embodiment of the present invention. In the embodiment, the semiconductor package includes a lead frame 20, a chip 30, an encapsulant 50, and a passive component 60. As shown in the figure, the lead frame 20 has a supporting element 22 and a plurality of leads 24, wherein any one of these leads 24 has an inner lead portion 25 and an outer lead portion 26; the chip 30 is arranged on the supporting element 22 in a appropriate method, such as the adhering method, and electrically connected with those inner lead portions 25 by utilizing a conductive connecting element 40; an encapsulant 50 covers the chip 30, the conductive connecting element 40 and those inner lead portions 25 of the lead frame 20, in one embodiment, the material of the encapsulant 50 includes epoxy; and a passive component 60 electrically connects with any two of those outer lead portions 26 of the lead frame 20, wherein the passive component 60 includes any one of resistor, capacitor and inductor.

Continuing the above description, in one embodiment, conductive connecting element 40 which can be composed of a plurality of wires electrically connects the active surface of the chip 30 to the inner lead portions 25 of the lead frame 20 by utilizing the wire bonding method. The material of the wires includes at least any one of gold (Au), copper (Cu), and Aluminum (Al).

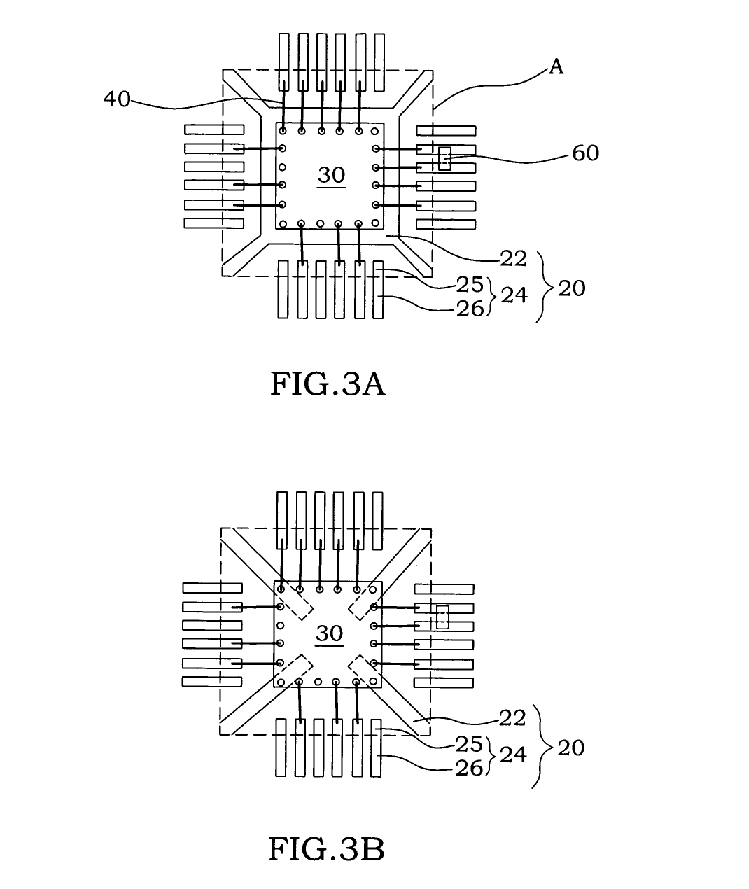

Referring to FIG. 3A, FIG. 3A is the top-view schematic diagram to illustrate the semiconductor package structure according to the first embodiment of the present invention. As shown in the figure, the lead frame 20 includes the supporting element 22 and a plurality of the leads 24, wherein every lead 24 can be defined as an inner lead portion 25 and an outer lead portion 26. In the embodiment, the supporting element 22 is a chip-bearing pad utilized to support the chip 30. Then, the chip 30 is electrically connected to the inner lead portions 25 of the lead frame 20 by utilizing a conductive connecting element 40 to transmit the signal. In the figure, area A denotes the predetermined packaging area, and the encapsulant 50 (as shown in FIG. 2) can cover the chip 30, the conductive connecting element 40 and the inner lead portions 25 of the lead frame 20 to protect and prevent the chip 30 and the conductive connecting element 40 from external particle damage. Besides, as shown in the figure, the passive component 60 is disposed on any two of the outer lead portions 26 of the lead frame 20, wherein the passive component 60 can be set on any one of the upper surface and the lower surface of the outer lead portions 26 (in the figure, the passive component 60 is set on the upper surface), and the passive component 60 is exposed to the encapsulant 50. Owing to the exposure arrangement, the connecting situation of the passive component 60 can be directly detected and the passive component 60 can be prevented from the damage by the encapsulant 50 during the molding process.

In another embodiment, as shown in FIG. 3B, the supporting element 22 of the lead frame 20 can also be composed of a plurality of supporting fingers. These supporting fingers can be utilized to support the chip 30, wherein the arranging position, the size, and the amount of the supporting fingers are not limited by which shown in the figure.

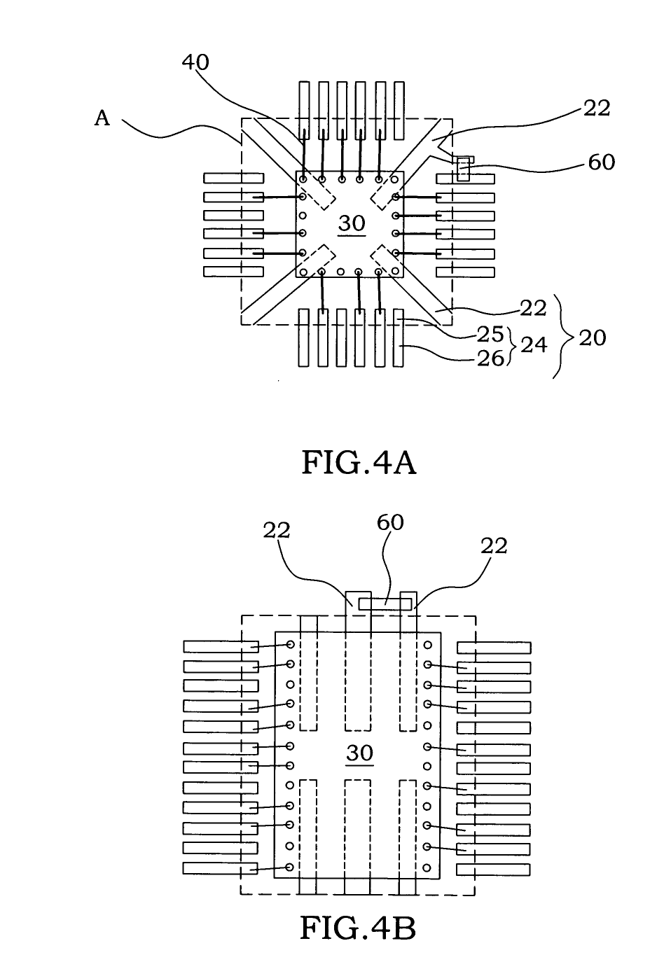

Please refer to FIG. 4A, FIG. 4A is the top-view schematic diagram to illustrate the semiconductor package structure according to the second embodiment of the present invention. The differences between the first embodiment and the second embodiment are the supporting element with a plurality of supporting fingers of the lead frame 20, which are utilized to support the chip 30, and the arranging position of the passive component 60. The detailed explanation is described in the following, the chip 30 is arranged on one end of the supporting element, and electrically connected to the inner lead portions 25 of the lead frame 20 with a conductive connecting element 40 to conduct electricity. As shown in the figure, area A denotes the predetermined packaging area, and the encapsulant 50 (as shown in FIG. 2) can cover the chip 30, the conductive connecting element 40, the inner lead portions 25 of the lead frame 20 and some portions of the supporting fingers. According to the circuit design of the lead frame 20, the passive component 60 can electrically be connected to any one of the exposed portion of the supporting fingers and any one of the outer lead portions 26. Wherein the exposed portion of the supporting fingers can be a bump protruded from the supporting fingers shown in the figure, but is not limited by this. Any supporting structure, which exposes to encapsulant 50 and can bear the passive component 60, is included in the scope of the present invention.

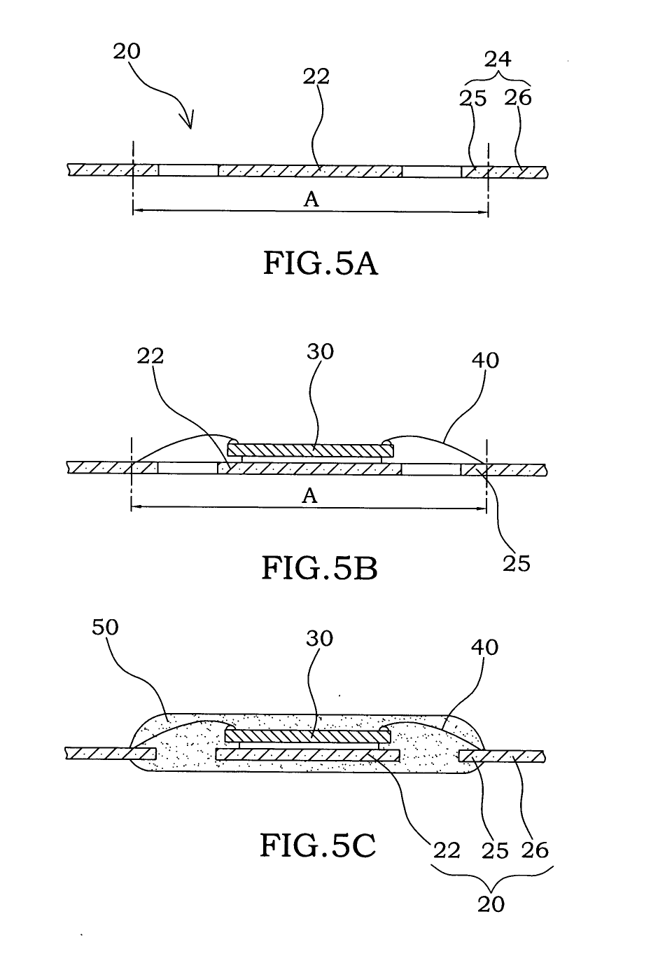

FIG. 5A, FIG. 5B and FIG. 5C are the cross-sectional schematic diagrams to illustrate the process steps of the semiconductor manufacturing method according to one embodiment of the present invention. Such as shown in FIG. 5A, firstly, a lead frame 20 is provided with a supporting element 22 and a plurality of leads 24, wherein any one of the leads 24 has an inner lead portion 25 and an outer lead portion 26, and the area A shown in the figure denotes the predetermined packaging area. In one embodiment, the supporting element 22 can be a chip-bearing pad or can be composed of a plurality of supporting fingers. Next, as shown in FIG. 5B, the chip 30 is disposed on the supporting element 22 by applying a proper way, and electrically connecting the chip 30 to the inner lead portions 25, in one embodiment, the proper way includes fixing and attaching the chip 30 on the supporting element 22 by utilizing a adhesion, a adhesive film, or a non-conductive epoxy. Further, as shown in FIG. 5C, forming an encapsulant 50 to cover the internal components such as the chip 30, the conductive connecting element 40, and the inner lead portions 25 by applying a proper way, for example, the molding method. The encapsulant 50 can protect these internal components and prevent them from the external damage or pollution, wherein the outer lead portions 26 exposed to the encapsulant 50 can be utilized to solder the lead frame 20 on a printed circuit board, so that the chip 30 can perform the predetermined function. Finally, arranging a passive component 60 (such as shown in FIG. 2) on at least any one of these outer lead portions 26 and the supporting element 22 by a proper way, for example a surface mount technology (SMT) method, to form the cross-sectional structure shown in FIG. 2. After that, according to the different design, these leads 24 of the lead frame 20 can be punched to form the needed shape, such as a L type, a J type, an I type, and so forth. In one embodiment, these leads 24 can be punched at first, and perform the SMT process of the passive component 60 (as shown in FIG. 2) later, but the sequence of these two steps can be exchanged according to the practical status.

Continuing the above description, in one embodiment, the chip 30 can be electrically connected with the inner lead portions 25 by utilizing a wire bonding method with a conductive connecting element 40, which can be a wire. In another embodiment according to the present invention, the process steps further include performing a package-testing process before disposing the passive component 60 on the lead frame 20, wherein the package-testing process includes examining whether the electricity transmission of the chip 30 is normal or not. If the electricity transmission is regular, the passive component 60 will be set on the top surface or the lower surface of the outer lead portion 26, so as to reduce the damage probability.

According to the above description, one feature of the present invention is the passive component can be set on the supporting element of the lead frame, on the outer lead portions or across the supporting element and outer lead portions in compliance with the various circuit designs. Additionally, the passive component can be disposed on any protrusion having electricity and exposed to the encapsulant. The passive component can be set on the upper surface or the lower surface of the lead frame, which process is very flexible. Besides, another feature of the present invention is to examine the electrical testing of the chip at first and disposing the passive component later, so as to improve the production yield and reduce the damage probability.

To summarize, the present invention provides a semiconductor package structure and its manufacturing method which the passive component exposed to the molding compound. After packaging the chip, the electrical testing can be performed at first and the passive component is disposed on the lead frame later, so that the damage probability of the passive component can be reduced. Additionally, the package structure and the passive component can be examined respectively, so as to improve the process reliability and reduce the production cost. Furthermore, the passive component is set exposed to the encapsulant, so that the connection of the passive component can be directly examined, and in addition, the passive component can be prevented from damaging during the molding process.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. A semiconductor package, comprising:
a lead frame with a supporting element and a plurality of leads, wherein any one of said leads has an inner lead portion and an outer lead portion;
a chip set on said supporting element, and electrically connected to said inner lead portions via a conductive connecting element;
an encapsulant covering said chip, said conductive connecting element and said inner lead portions; and
a passive component electrically connected with any two of said outer lead portions.

2. The semiconductor package according to claim 1, wherein said supporting element is a chip-bearing pad.

3. The semiconductor package according to claim 1, wherein said supporting element is a plurality of supporting fingers.

4. The semiconductor package according to claim 1, wherein said passive component is exposed to said encapsulant.

5. The semiconductor package according to claim 1, wherein said conductive connecting element comprises a plurality of wires.

6. The semiconductor package according to claim 5, wherein the material of said wires comprises gold (Au), copper (Cu), or aluminum (Al).

7. The semiconductor package according to claim 1, wherein the material of said encapsulant comprises epoxy.

8. The semiconductor package according to claim 1, wherein said passive component comprises any one of resistor, capacitor, and inductor.

9. A semiconductor package, comprising:
a lead frame with a supporting element and a plurality of leads, wherein said supporting element has a plurality of supporting fingers and any one of said leads has an inner lead portion and an outer lead portion;
a chip set on one side of said supporting element, and electrically connected to said inner lead portions via a conductive connecting element;
an encapsulant covering said chip, said conductive connecting element, said inner lead portions, and partial said supporting fingers; and
a passive component electrically connected with at least any one of exposed said supporting fingers and said outer lead portions.

10. The semiconductor package according to claim 9, wherein said passive component is exposed to said encapsulant.

11. The semiconductor package according to claim 9, wherein said passive component is arranged on any two of said supporting fingers.

12. The semiconductor package according to claim 9, wherein said passive component is arranged on any one of said supporting fingers and any one of said outer lead portions.

13. The semiconductor package according to claim 9, wherein said conductive connecting element comprises a plurality of wires.

14. The semiconductor package according to claim 13, wherein the material of said wires comprises gold (Au), copper (Cu), or aluminum (Al).

15. The semiconductor package according to claim 9, wherein the material of said encapsulant comprises epoxy.

16. The semiconductor package according to claim 9, wherein said passive component comprises any one of resistor, capacitor, and inductor.

17. A manufacturing method for a semiconductor package, comprising:
providing a lead frame with a supporting element and a plurality of leads, wherein any one of said leads has an inner lead portion and an outer lead portion;
disposing a chip on said supporting element, and electrically connecting said chip to said inner lead portions via a conductive connecting element;
forming an encapsulant to cover said chip, said conductive connecting element and said inner lead portions; and
disposing a passive component on at least any one of said outer lead portions and said supporting element.

18. The manufacturing method for a semiconductor package according to claim 17, wherein methods of disposing said chip on said supporting element comprise using a adhesive, a adhesive film or a non-conductive epoxy to attach on said supporting element.

19. The manufacturing method for a semiconductor package according to claim 17, wherein a method of electrically connecting said chip to said inner lead portions comprise a wire bonding method.

20. The manufacturing method for a semiconductor package according to claim 17, wherein methods of forming said encapsulant comprises a molding method.

21. The manufacturing method for a semiconductor package according to claim 17, further comprising performing a package-testing process before arranging said passive component.

22. The manufacturing method for a semiconductor package according to claim 21, wherein said package-testing process comprises testing the electricity transmission of said chip.

23. The manufacturing method for a semiconductor package according to claim 17, wherein methods of disposing said passive component on any one of said outer lead portions and said supporting element comprise a surface mount technology method.
